(19) United States
(12) Patent Application Publication
(10) Pub. No.: US 2012/0186572 A1
(43) Pub. Date: Jul. 26, 2012

(54) SILICON WAFER SAWING FLUID AND PROCESS FOR USE THEREOF

(76) Inventors: Helmuth Treichel, Milpitas, CA (US); Dave Bohling, Fort Collins, CO (US); Mark George, Tucson, AZ (US)

(21) Appl. No.: 13/387,937

(22) PCT Filed: Jul. 28, 2010
(86) PCT No.: PCT/US10/43509

§ 371 Date: Apr. 16, 2012

Related U.S. Application Data
(60) Provisional application No. 61/229,084, filed on Jul. 28, 2009.

(51) Int. Cl. H01L 21/301; B28D 5/00; B23Q 11/10

(52) U.S. Cl. 125/21

(57) ABSTRACT

A process is provided in which a metal chelating agent is dissolved in an aqueous or glycol-based cooling fluid to form a chelating solution with a chelating agent concentration. A silicon boule is cut with a saw to detach a silicon wafer from the boule while the interface between the silicon boule and the saw is bathed with the chelating solution during the cutting.

### FIELD OF THE INVENTION

This application claims priority benefit of U.S. Provisional Application Ser. No. 61/229,084 filed 28 Jul. 2009; the contents of which are hereby incorporated by reference.

### FIELD OF THE INVENTION

The present invention in general relates to sectioning of silicon boules into wafers and in particular to a fluid for use during silicon boule sectioning that reduces the concentration of contaminants in the resultant silicon wafers.

### BACKGROUND OF THE INVENTION

Large cross section substrates of silicon are commonly used for the manufacture of microelectronics and photovoltaic cells. The purity of silicon wafer substrate has implications in the performance of devices constructed using a silicon wafer as a substrate. Owing to the economics of photovoltaics, in particular, little attention has been paid to contaminant loading of in general silicon wafers and in particular to photovoltaic silicon substrates. This problem has been further compounded by the fact that a producer of photovoltaic silicon wafer substrates is concerned with low cost production of such substrates while a photovoltaic manufacturer emphasizes the efficiency of the photovoltaic manufacture process on the silicon wafer substrate largely as delivered by the substrate producer. As such, neither the substrate producer nor the photovoltaic manufacturer has claimed ownership of the problem of silicon wafer contamination.

The formation of silicon wafers from silicon boules typically involves cooling fluid sawing using either blades or wires, and fixed abrasive sawing using the ID saw or by the FAST method in which the abrasive attached to the wires is arranged in a blade pack. The common feature of all these methodologies is that the silicon is exposed to extreme fast transient temperatures and forces during the sawing process as well as being imparted with contaminants from the sawing abrasive and/or wire. Of these contaminants imparted to a silicon substrate through the sawing process, metals are considered to be particularly troublesome in changing the silicon carrier concentration and therefore the semiconducting properties of the silicon wafer.

Thus, there exists a need for a sawing cooling fluid that inhibits contamination of the resultant silicon wafer in the course of the sawing process. There further exists a need for a sawing process that produces silicon wafer substrates with lower contaminant levels so as to produce higher efficiency photovoltaic devices therefrom.

### SUMMARY OF THE INVENTION

A process is provided in which a metal chelating agent is dissolved in an aqueous or glycol-based cooling fluid to form a chelating solution with a chelating agent concentration. A silicon boule is cut with a saw to detach a silicon wafer from the boule while the interface between the silicon boule and the saw is bathed with the chelating solution during the cutting. A biogradeable metal chelating agent is provided that has the formula:

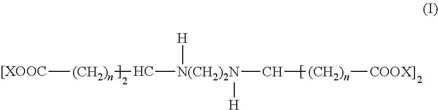

where n in each occurrence is independently an integer value between 0 and 6, and X in each occurrence is independently H, ammonium, Li, Na, K, or NR₄; where R in each occurrence is independently H or C₁-C₆ alkyl.

### DETAILED DESCRIPTION OF THE PREFERRED EMBODIMENTS

The present invention has utility in the inhibition of a silicon substrate becoming contaminated through a wafer sawing process. Through reduction of silicon wafer contamination, improved electrical performance results in a device built from the silicon substrate.

A representative wafer saw has a high tensile steel core overlayered with an electrolytic copper sheath that in turn has a nickel alloy overstrike on the wire. The nickel overstrike secures abrasive particulate such as diamond dust, silicon carbide, tungsten carbide or other abrasive to the surface of the wire. During a sawing operation, this wire experiences considerable frictional forces. Additionally, the abrasive also scours metal from the interior of the cutting wire with the removed metal contacting the silicon being cut. While e.g., water is used as a cooling fluid during cutting operations to mitigate frictional heating during the sawing process, this cooling fluid also serves to transmit the metal particulate or soluble metal ions to contact with the wafer as it is being sawed. From an interfacial reaction standpoint, this presents a significant problem in that the freshly cut silicon can be very reactive from an electrochemical reduction/oxidation standpoint particularly in an environment as described with high transient temperatures. This environment likely readily reduces or alloys metal ions (depending on the E°^{′} of the metal ion reduction-oxidation reaction in relation to bare Si) and incorporating metal from the saw into the interfacial silicon boundary.

An inventive silicon sawing cooling fluid is an aqueous or glycol solution containing a chelating agent.

As used herein with respect to chelating agents, specifically including alkyleneamine acids, such as ethylenediamine disuccinic acid (EDDS), ethylenediamine dimalonic acid (EDDM), and ethylenediamine diglutaric acid (EDDG), ethylenediaminetetraacetic acid (EDTA), diethylenetriaminepentaacetic acid (DTPA), nitrilotriacetic acid (NTA), iminodiacetic acid (IDA), iminotriacetic acid (ITA), ethylenediamine (En), N,N′-diethylenediamine (Den), diethylenetriamine (DTN), diethylenetetramine (Trien), triaminotriethylene amine, citric acid, and propylenediamine. It is appreciated that the salts of such acids are also operative herein and intended to be encompassed by reference to such chelating agents. Ammonium salts and acids are appreciated to limit the introduction of chelating agent cations into the substrate.

Preferably, the cooling fluid contains as a chelating agent an ethylenediamine acid having the formula

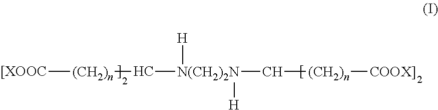

where n in each occurrence is independently an integer value between 0 and 6, and X is H, NR₄, Li, Na or K; where R in each occurrence is independently H or C₁-C₆ alkyl. Preferably, R in all occurrences are the same. Illustrative specific examples of NR₄ are ammonium cation, tetramethyl ammonium and tetraethylammonium.

Representative ethylenediamine acids of Formula I include ethylenediamine disuccinic acid (EDDS), ethylenediamine dimalonic acid (EDDM), and ethylenediamine diglutaric acid (EDDG). It is appreciated that an inventive ethylenediamine tetraacid of Formula I has a greater K_{f} (Reaction Constant) than ethylenediamine tetraacetic acid (EDTA) for copper and are biodegradable. Additionally, like EDTA, ethylenediamine tetraacids used herein are compatible at both acidic and basic pHs while being biodegradeable. Optionally, the cooling fluid contains sodium (or ammonium) citrate operative at acidic pHs to bind metal ions and in particular calcium 2+ ions.

A diethylenediamine tetraacid (I) is present in concentrations ranging from 5 to 100000 parts per million.

Optionally, an inventive fluid contains a surfactant to facilitate substrate wetting and action of the chelating agent. A surfactant is typically present form 0.001 to 1 percent by weight of the fluid. Other optionally additives to the cooling fluid include pH buffers, crown ethers selected to chelate specific metal ions associated with the sawing process. Usage of an inventive chelating agent in the presence of HCl, alone or in combination with other conventional metal oxidizers such as hydrogen peroxide is appreciated to promote oxidation of metal atoms, such as iron smeared on the wafer surface to enhance the kinetics of chelating agent bonding and removal from the silicon surface.

Without intending to be bound to a particular theory, it is believed that in the event that e.g., water cooling is inadequate then diffusion and/or alloying of various metals associated with the cutting wire occurs. This diffusion and alloying of metals from the wire is believed to occur well before the abrasive undergoes oxidative failure. The localized and instantaneous heating is believed to be considerable thereby causing fast solid diffusion associated with a concentration gradient metal along the abrasive particle grain boundaries.(Fe is known to migrate in Si at room temperature, so once it is bound to the Si surface in the form of a silicide it will diffuse).

Subsequent to silicon sawing, it is conventional that the removed substrate is washed with deionized water to remove debris. According the the present invention, the metal chelating agent is optionally added to the deionized water to provide an additional opportunity to scavenge contaminants from the substrate, with an optional follow-on pure deionized water wash. Alternatively, a wafer is exposed to a melt of a metal chelating agent (I) followed by conventional deionized water rinse.

In addition to a photovoltaic (solar) substrate other substrates amenable to an inventive cleaning process include a bare or pure silicon substrate, with or without doping, a substrate with epitaxial layers, a substrate incorporating one or more device layers at any stage of processing, other types of substrates incorporating one or more layers, or substrates for processing other apparatus and devices such as flat panel displays, and multichip modules. However, to avoid obscuring the invention the following description will describe photovoltaic (solar) substrate cleaning in general and as an example of one embodiment will describe the use of the present invention in a scrubbing process. While the present invention has been detailed with respect to silicon wafer sawing, it is appreciated that the inventive process and cooling fluid are also well employed in the formation of other types of substrates such as GaAs and InP.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process comprising:
dissolving a metal chelating agent in an aqueous or glycol-based cooling fluid to form a chelating solution with a chelating agent concentration;
friction sawing a silicon boule with a saw to detach a silicon wafer therefrom; and
bathing an interface between said silicon boule and said saw with said chelating solution during the friction sawing.

2. The process of claim 1 wherein said metal chelating agent has the formula: 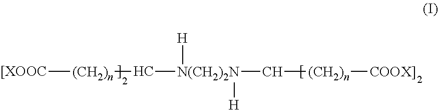
where n in each occurrence is independently an integer value between 0 and 6, and X is H, ammonium, Li, Na, K, or NR₄; where R in each occurrence is independently H or C₁-C₆ alkyl.

3. The process of claim 1 wherein said metal chelating agent is ethylene diamine disuccinic acid or a salt thereof.

4. The process of claim 1 wherein said metal chelating agent is an ammonium salt.

5. The process of claim 1 wherein said chelating agent is present in a concentration of between 5 and 100000 parts per million by weight.

6. The process of claim 2 wherein R is the same in every occurrence.

7. The process of claim 6 wherein R is H in every occurrence.

8. The process of claim 1 further comprising rinsing said silicon wafer with deionized water.

9. The process of claim 8 further comprising adding said metal chelating agent to said deionized water.

10. The process of claim 9 wherein said metal chelating agent is present at a concentration in said deionized water that is less than the chelating agent concentration.

11. The process of claim 1 further comprising a pH buffering agent in said chelating solution.

12. The process of claim 1 further comprising a surfactant in said chelating solution.
